(19) United States
(12) Patent Application Publication
(10) Pub. No.: US 2026/0123524 A1
(43) Pub. Date: Apr. 30, 2026

(54) SEMICONDUCTOR PACKAGE

(71) Applicant: Samsung Electronics Co., Ltd., Suwon-si (KR)

(72) Inventors: Haseob Seong, Suwon-si (KR); Dawoon Jung, Suwon-si (KR)

(21) Appl. No.: 19/248,828

(22) Filed: Jun. 25, 2025

(30) Foreign Application Priority Data
Oct. 25, 2024 (KR) 10-2024-0147620

(51) Int. Cl. H01L 23/24; H01L 23/00; H01L 23/31; H01L 23/48; H01L 25/18; H10B 80/00; H10D 80/30

(52) U.S. Cl. CPC H10W 76/47; H10B 80/00; H10D 80/30; H10W 90/00; H10W 20/20; H10W 74/131; H10W 90/297; H10W 90/734; H10W 90/792

(57) ABSTRACT

A semiconductor package includes a base structure; a semiconductor chip stack stacked on the base structure in a vertical direction and electrically connected to the base structure, and including a plurality of semiconductor chips wherein the plurality of semiconductor chips include a lowermost semiconductor chip; a dummy chip on the semiconductor chip stack; a joint film between the dummy chip and the semiconductor chip stack; a plurality of joint patterns spaced apart from the plurality of semiconductor chips on the base structure; and an encapsulant wherein the lower pads of the semiconductor chips stacked on the lowermost semiconductor chip among the plurality of semiconductor chips are in contact with the upper pads of the semiconductor chips respectively disposed therebelow.

### CROSS-REFERENCE TO RELATED APPLICATION(S)

This application claims benefit of priority under 35 U.S.C. § 119 to Korean Patent Application No. 10-2024-0147620 filed on Oct. 25, 2024 in the Korean Intellectual Property Office, the disclosure of which is incorporated herein by reference in its entirety.

### BACKGROUND

The present inventive concept relates to a semiconductor package.

With the development of the electronics industry and the demands of users, electronic devices are becoming increasingly smaller and lighter, and semiconductor packages used in electronic devices are required to be smaller and lighter, as well as to have high performance and large capacities. In order to realize high performance and a large amount of capacity along with miniaturization and lightness, research and development are continuously being conducted on semiconductor chips including through-electrodes and semiconductor packages in which the semiconductor chips are stacked.

### SUMMARY

An aspect of the present inventive concept provides a semiconductor package having improved reliability.

According to an aspect of the present inventive concept, a semiconductor package includes a base structure including a base substrate, upper connection pads on an upper surface of the base substrate, and an upper bonding insulating layer covering the upper surface of the base substrate and surrounding side surfaces of the upper connection pads; a semiconductor chip stack stacked on the base structure in a vertical direction and electrically connected to the base structure, and including a plurality of semiconductor chips having lower pads located on a lower surface, upper pads on an upper surface, and through-electrodes electrically connecting the lower pads and the upper pads, wherein the plurality of semiconductor chips include a lowermost semiconductor chip, and the lower pads of the lowermost semiconductor chip are in contact with the upper connection pads; a dummy chip on the semiconductor chip stack; a joint film between the dummy chip and the semiconductor chip stack; a plurality of joint patterns spaced apart from the plurality of semiconductor chips on the base structure; and an encapsulant covering at least a portion of the semiconductor chip stack, the dummy chip, the joint film, and each of the plurality of joint patterns, on the base structure, wherein the lower pads of the semiconductor chips stacked on the lowermost semiconductor chip among the plurality of semiconductor chips are in contact with the upper pads of the semiconductor chips respectively disposed therebelow.

According to an aspect of the present inventive concept, a semiconductor package includes a base structure including a base substrate and upper connection pads on an upper surface of the base substrate; a semiconductor chip stack including a plurality of semiconductor chips stacked on the base structure in a vertical direction; a joint pattern spaced apart from the semiconductor chip stack on the base structure; a joint film covering an upper portion of the semiconductor chip stack; and a dummy chip on the joint film, wherein the plurality of semiconductor chips include a first semiconductor chip located in a lowermost portion of the semiconductor chip stack, and including first lower pads on a lower surface, first upper pads on an upper surface, and first through-electrodes electrically connecting the first lower pads and the first upper pads; and a second semiconductor chip located in an uppermost portion of the semiconductor chip stack and including second lower pads on a lower surface, the first lower pads are in contact with the upper connection pads, the joint film protrudes further in a horizontal direction than each of the dummy chip and the plurality of semiconductor chips, and the joint film covers at least a portion of a side surface of the second semiconductor chip.

According to an aspect of the present inventive concept, a semiconductor package includes a base structure including a base substrate, upper connection pads on an upper surface of the base substrate, and an upper bonding insulating layer covering the upper surface of the base substrate and surrounding side surfaces of the upper connection pads; a semiconductor chip stack on the base structure and electrically connected to the upper connection pads, wherein the semiconductor chip stack includes a lowermost semiconductor chip located on a lowermost level; joint patterns on the upper bonding insulating layer to be spaced apart from the semiconductor chip stack; and an encapsulant covering the semiconductor chip stack and the joint patterns on the upper surface of the base substrate, wherein the lowermost semiconductor chip includes lower pads on a lower surface, and a lower insulating layer surrounding side surfaces of the lower pads, the lower pads are in contact with the upper connection pads, and the lower insulating layer is in contact with the upper bonding insulating layer.

### BRIEF DESCRIPTION OF DRAWINGS

The above and other aspects, features, and advantages of the present inventive concept will be more clearly understood from the following detailed description, taken in conjunction with the accompanying drawings, in which:

FIG. 1 is a schematic cross-sectional view illustrating a semiconductor package according to example embodiments.

FIG. 2 is a schematic plan view illustrating a semiconductor package according to example embodiments.

FIG. 3 is a schematic partial enlarged view illustrating portion ‘A’ of the semiconductor package of FIG. 1 according to example embodiments.

FIGS. 4A to 4C are schematic partial enlarged views illustrating portion ‘A’ of the semiconductor package of FIG. 1 according to example embodiments.

FIGS. 5 and 6 are schematic cross-sectional views illustrating a semiconductor package according to example embodiments.

FIGS. 7 to 12 are schematic plan views illustrating a semiconductor package according to example embodiments.

FIG. 13A is a schematic plan view illustrating a semiconductor package according to example embodiments.

FIG. 13B is a schematic cross-sectional view illustrating a semiconductor package according to example embodiments.

FIGS. 14, 15, 16A, 17A, and 18 are cross-sectional views illustrating in a process sequence of a method for manufacturing a semiconductor package according to example embodiments.

FIGS. 16B and 17B are partial enlarged views illustrating portion ‘A’ of FIGS. 16A and 17A respectively in a process sequence to illustrate a method for manufacturing a semiconductor package according to example embodiments.

### DETAILED DESCRIPTION

Hereinafter, preferred embodiments will be described with reference to the attached drawings. Hereinafter, terms such as ‘on,’ ‘upper,’ ‘upper portion,’ ‘upper surface,’ ‘below,’ ‘lower,’ ‘lower portion,’ ‘lower surface,’ ‘side surface,’ and the like can be understood to refer to the drawings unless otherwise explained. For example, spatially relative terms, such as “beneath,” “below,” “lower,” “above,” “upper,” “top,” “bottom,” “front,” “rear,” and the like, may be used herein for ease of description to describe positional relationships, such as illustrated in the figures, for example. It will be understood that the spatially relative terms encompass different orientations of the device in addition to the orientation depicted in the figures.

Throughout the specification, when a component is described as “including” a particular element or group of elements, it is to be understood that the component is formed of only the element or the group of elements, or the element or group of elements may be combined with additional elements to form the component, unless the context clearly and/or explicitly describes the contrary.

As used herein, components described as being “electrically connected” are configured such that an electrical signal can be transferred from one component to the other (although such electrical signal may be attenuated in strength as it is transferred and may be selectively transferred).

It will be understood that when an element is referred to as being “connected” or “coupled” to or “on” another element, it can be directly connected or coupled to or on the other element or intervening elements may be present. In contrast, when an element is referred to as being “directly connected,” “directly attached,” “directly joined,” or “directly coupled” to another element, or as “contacting” or “in contact with” another element (or using any form of the word “contact”), there are no intervening elements present at the point of contact.

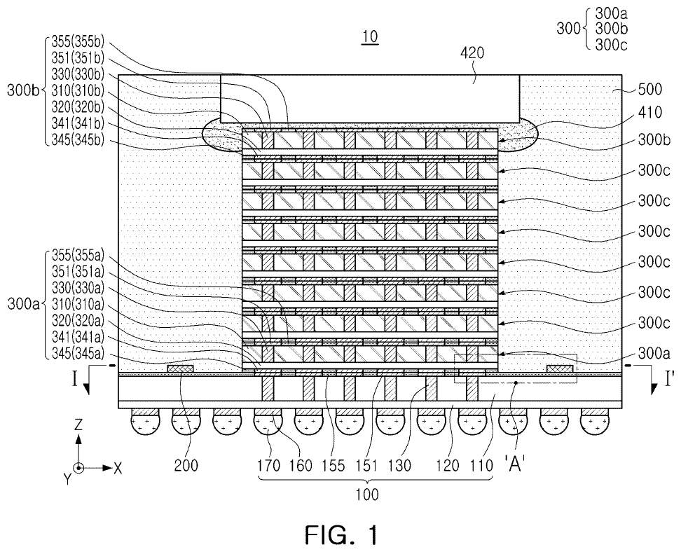

FIG. 1 is a schematic cross-sectional view illustrating a semiconductor package according to example embodiments.

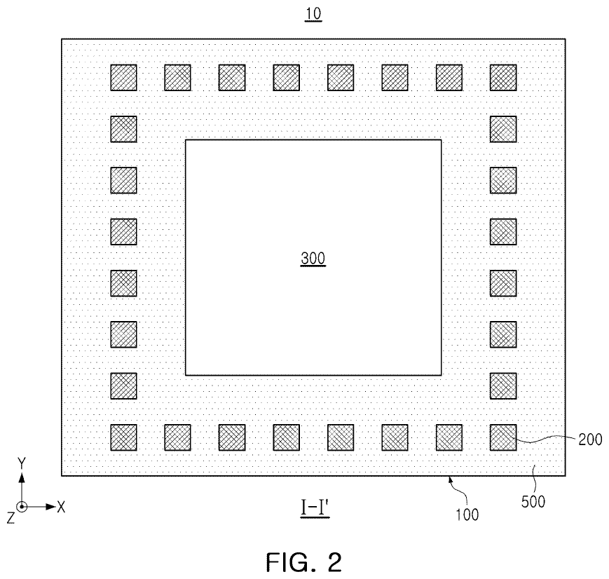

FIG. 2 is a schematic plan view illustrating a semiconductor package according to example embodiments. FIG. 2 schematically illustrates a plan view of the semiconductor package of FIG. 1, along a plane taken along line I-I′ of FIG. 1.

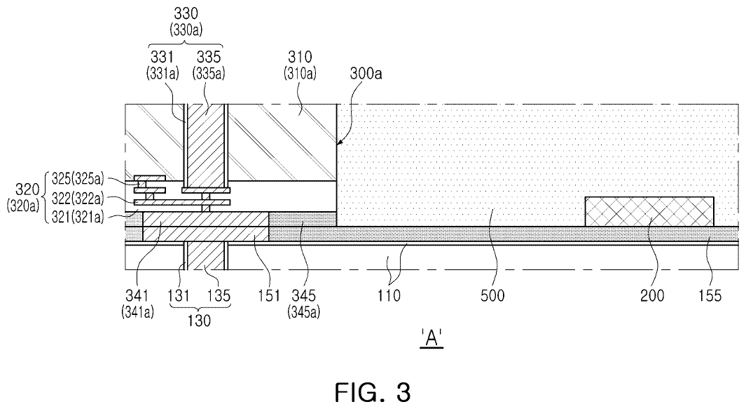

FIG. 3 is a schematic partial enlarged view illustrating a semiconductor package according to example embodiments. FIG. 3 is an enlarged view of portion ‘A’ of FIG. 1.

Referring to FIGS. 1 to 3, a semiconductor package 10 may include a base structure 100, joint patterns 200, a semiconductor chip stack 300 including a plurality of semiconductor chips 300a, 300b, and 300c, a joint film 410, a dummy chip 420, and an encapsulant 500.

The base structure 100 may be, for example, a buffer chip including a plurality of logic elements and/or a plurality of memory elements in a base element layer 120. Therefore, the base structure 100 may transmit a signal from the plurality of semiconductor chips 300a, 300b, and 300c, stacked thereon, to the outside, and may also transmit a signal and power from the outside to the plurality of semiconductor chips 300a, 300b, and 300c. The base structure 100 may perform both a logic function and a memory function through the logic elements and the memory elements, but according to an embodiment, the base structure 100 may perform only the logic function by including only the logic elements. The base structure 100 may include a base substrate 110, a base element layer 120, a connection via 130, upper connection pads 151, an upper bonding insulating layer 155, lower connection pads 160, and connection conductors 170.

The base substrate 110 may include a semiconductor element, such as silicon or germanium (Ge), for example, or may include a compound semiconductor, such as silicon carbide (SiC), gallium arsenide (GaAs), indium arsenide (InAs), or indium phosphide (InP). The base substrate 110 may have a silicon-on-insulator (SOI) structure. The base substrate 110 may include a conductive region, for example, a well doped with an impurity, or a structure doped with an impurity. The base substrate 110 may include various device isolation structures, such as a shallow trench isolation (STI) structure. The base substrate 110 may include an insulating layer on an upper surface thereof contacting the upper connection pads 151 and the upper bonding insulating layer 155. In this specification, the horizontal direction may be a direction, parallel to an upper surface of the base substrate 110, and the vertical direction may be a direction, perpendicular to the upper surface of the base substrate 110. For example, the horizontal direction may be an X-direction or a Y-direction, and the vertical direction may be a Z-direction.

The base element layer 120 may be disposed on a lower surface of the base substrate 110, and may include various types of elements. For example, the base element layer 120 may include a field effect transistor (FET) such as a planar FET, a FinFET, or the like, a memory element such as a flash memory, a dynamic random access memory (DRAM), a static random access memory (SRAM), an electrically erasable programmable read-only memory (EEPROM), a phase-change random access memory (PRAM), a magnetoresistive random access memory (MRAM), a ferroelectric random access memory (FeRAM), a resistive random access memory (RRAM), or the like, a logic elements such as AND, OR, NOT, or the like, various active elements and/or passive elements such as a system large scale integration (LSI), a CMOS imaging sensor (CIS), a micro-electro-mechanical system (MEMS), or the like, but the elements included in the base element layer 120 are not limited to these. The above-described elements may include an interlayer insulating layer (not illustrated) and a multilayer interconnection layer (not illustrated). The interlayer insulating layer (not illustrated) may include silicon oxide or silicon nitride. The multilayer interconnection layer (not illustrated) may include a multilayer interconnection and/or a vertical contact. The multilayer interconnection layer (not illustrated) may electrically connect elements of the base element layer 120 to each other, electrically connect the elements to a conductive region of the base substrate 110, and/or electrically connect the elements to the lower connection pads 160.

The connection vias 130 may penetrate the base substrate 110 in the vertical direction (Z-direction), and may provide an electrical path electrically connecting the upper connection pads 151 and the lower connection pads 160. The connection vias 130 may be electrically connected to the plurality of semiconductor chips 300a, 300b, and 300c. The connection vias 130 may include a conductive plug 135 and a side insulating film 131 surrounding the conductive plug. The conductive plug 135 may include a metal material, for example, tungsten (W), titanium (Ti), aluminum (Al), copper (Cu), titanium (Ti), titanium nitride (TiN), tantalum (Ta), or tantalum nitride (TaN). The conductive plug 135 may be formed by a plating process, a PVD process, or a CVD process. The side insulating film 131 may include an insulating material such as silicon oxide, silicon nitride, silicon oxynitride, or the like (for example, a high aspect ratio process (HARP) oxide).

The upper connection pads 151 may be disposed on the upper surface of the base substrate 110. The upper connection pads 151 may be directly joined to first lower pads 341a of a first semiconductor chip 300a located in a lowermost portion of the semiconductor chip stack 300. The plurality of semiconductor chips 300a, 300b, and 300c may be electrically connected to the base structure 100 on and through the upper connection pads 151. The upper connection pads 151 may have flat upper surfaces, and may be coplanar with an upper surface of the upper bonding insulating layer 155. When the upper surfaces of the upper connection pads 151 are joined to lower surfaces of the first lower pads 341a, an interface therebetween may be unclear. The upper connection pads 151 may include a conductive material. The upper connection pads 151 may include copper (Cu), but are not limited thereto. For example, the upper connection pads 151 may include at least one of aluminum (Al), nickel (Ni), tungsten (W), platinum (Pt), or gold (Au).

The upper bonding insulating layer 155 may surround/contact side surfaces of the upper connection pads 151 on the upper surface of the base substrate 110. The upper bonding insulating layer 155 may be in contact with a first lower insulation layer 345a of the first semiconductor chip 300a located in the lowermost portion of the semiconductor chip stack 300. The upper bonding insulating layer 155 may have a flat upper surface, and may be coplanar with the upper surfaces of the upper connection pads 151. The upper bonding insulating layer 155 may include an insulating material. The upper bonding insulating layer 155 may include, for example, silicon oxide, silicon nitride, or a combination thereof, and may include a plurality of insulating layers.

The lower connection pads 160 may be disposed on a lower surface of the base element layer 120, below the base substrate 110, and at a lower portion of the base structure 100. For example, the lower connection pads 160 may be disposed below the base element layer 120. The lower connection pads 160 may be electrically connected to the upper connection pads 151 through the connection vias 130. The lower connection pads 160 may include a conductive material. The lower connection pads 160 may include, for example, at least one of copper (Cu), aluminum (Al), nickel (Ni), tungsten (W), platinum (Pt), or gold (Au).

The connection conductors 170 may be disposed below the lower connection pads 160. The connection conductors 170 may be electrically connected to the plurality of semiconductor chips 300a, 300b, and 300c through the connection vias 130. The connection conductors 170 may include, for example, tin (Sn) or an alloy including tin (Sn) (for example, Sn-Ag-Cu). The connection conductors 170 may be electrically connected to an external device such as a module substrate, a system board, or the like. The connection conductors 170 may contact bottom surfaces of the lower connection pads 160, respectively.

The joint patterns 200 may be disposed on the base structure 100 to be spaced apart from the semiconductor chip stack 300. The joint patterns 200 may be disposed to surround the semiconductor chip stack 300. The joint patterns 200 may be disposed on the upper bonding insulating layer 155 of the base structure 100. Lower surfaces of the joint patterns 200 may be located on the same level as a lower surface of the lowermost semiconductor chip 300a. The joint patterns 200 may be spaced apart from the base substrate 110 by the upper bonding insulating layer 155, and may be electrically isolated from the upper connection pads 151, the connection vias 130, or the like included in the base structure 100. For example, the joint patterns 200 may be electrically isolated from the base structure 100. Upper surfaces of the joint patterns 200 may be located on a higher level than upper surfaces of the first lower pads 341a. For example, the joint patterns 200 may be thicker than the first lower pads 341a. Each of the joint patterns 200 may have a width greater than its height. The joint patterns 200 may include a material (e.g., a polymer) having a high bonding force with the encapsulant 500, or may serve to increase arithmetic mean roughness (Ra) of the upper surface of the base structure 100, thereby increasing bonding force between the base structure 100 and the encapsulant 500. The arithmetic mean roughness (Ra) may be an average value of an absolute value deviation from a center line (reference/mean line) of a surface profile to an actual surface. The joint patterns 200 may include, but are not limited to, a polymer or a metal. In an embodiment, the joint patterns 200 may include a material, the same as a material of the upper bonding insulating layer 155.

The semiconductor chip stack 300 may include memory chips or memory elements/devices that store or output data, based on an address command, a control command, or the like, received from the base structure 100. For example, the plurality of semiconductor chips 300a, 300b, and 300c may include volatile memory elements/chips such as DRAM and SRAM, or non-volatile memory elements/chips such as PRAM, MRAM, FeRAM, or RRAM. In the plurality of semiconductor chips 300a, 300b, and 300c, upper and lower surfaces thereof may be in contact with and may be electrically connected and/or bonded to each other, without a separate solder interposed therebetween. For example, the plurality of semiconductor chips 300a, 300b, and 300c may be attached to each other with no layer or material interposed therebetween. In FIG. 1, it is illustrated that the semiconductor chip stack 300 has eight semiconductor chips stacked together therein, but the number of semiconductor chips included in the semiconductor chip stack 300 is not limited thereto. For example, the semiconductor chip stack 300 may include fewer or more semiconductor chips than the number illustrated in FIG. 1. In an embodiment, the semiconductor chip stack 300 may include four, eight, twelve, or sixteen semiconductor chips, which are multiples of four.

The plurality of semiconductor chips 300a, 300b, and 300c may include a first semiconductor chip 300a located in the lowermost portion of the chip stack 300, a second semiconductor chip 300b located in an uppermost portion of the chip stack 300, and third semiconductor chips 300c stacked between the first semiconductor chip 300a and the second semiconductor chip 300b. The first semiconductor chip 300a may be a lowermost semiconductor chip 300a among the semiconductor chips, the second semiconductor chip 300b may be an uppermost semiconductor chip 300b among the semiconductor chips, and the third semiconductor chips 300c may be intermediate semiconductor chips 300c disposed between the lowermost semiconductor chip 300a and the uppermost semiconductor chip 300b. Each of the plurality of semiconductor chips 300a, 300b, and 300c may include a semiconductor substrate 310, a semiconductor device layer 320, through-electrodes 330, lower pads 341, a lower insulating layer 345, upper pads 351, and an upper insulating layer 355.

The semiconductor substrate 310 may have a lower surface on which the semiconductor device layer 320 is disposed, and an upper surface located opposite to the lower surface. The lower surface of the semiconductor substrate 310 may be an active surface, and the upper surface may be an inactive surface. The semiconductor substrate 310 may include, for example, a semiconductor element such as silicon or germanium (Ge), or may include a compound semiconductor such as silicon carbide (SiC), gallium arsenide (GaAs), indium arsenide (InAs), or indium phosphide (InP). The semiconductor substrate 310 may have a silicon-on-insulator (SOI) structure. The semiconductor substrate 310 may include a conductive region, for example, a well doped with an impurity, or a structure doped with an impurity. The semiconductor substrate 310 may include various device isolation structures, such as a shallow trench isolation (STI) structure.

The semiconductor device layer 320 may include a metal interconnection layer 322, a metal via 325, and an interlayer insulating layer 321 covering/contacting them (the metal interconnection layer 322 and the metal via 325), which may be connected to a plurality of individual devices formed on an active surface of the semiconductor substrate 310. For example, the metal interconnection layer 322 and the metal via 325 may be electrically connected to the individual devices formed in/on the semiconductor substrate 310. In an embodiment, the semiconductor device layer 320 may be a multilayer structure including two or more metal interconnection layers 322 and/or two or more metal vias 325. The metal interconnection layer 322 may be electrically connected to the lower pads 341 through the metal via 325. The interlayer insulating layer 321 may cover the active surface, i.e., the lower surface, of the semiconductor substrate 310, and may include a plurality of insulating layers.

The through-electrodes 330 may have a columnar structure penetrating the semiconductor substrate 310 in a vertical direction. Upper ends of the through-electrodes 330 may be electrically connected to and/or contact the upper pads 351, and lower ends thereof may be electrically connected to the lower pads 341 through the metal interconnection layer 322 and the metal via 325. In this manner, the through-electrodes 330 may electrically connect the lower pads 341 and the upper pads 351. Each of the through-electrodes 330 may include an electrode plug 335 and an insulating liner 331 surrounding the electrode plug 335. The insulating liner 331 may electrically isolate the electrode plug 335 from the semiconductor substrate 310. The electrode plug 335 may include a metal material (or a metal), for example, tungsten (W), titanium (Ti), aluminum (Al), copper (Cu), titanium (Ti), titanium nitride (TiN), tantalum (Ta), or tantalum nitride (TaN), and may be formed by a plating process, a PVD process, or a CVD process. The insulating liner 331 may include an insulating material such as silicon oxide, silicon nitride, silicon oxynitride, or the like (for example, a high aspect ratio process (HARP) oxide).

The lower pads 341 may be disposed below the semiconductor device layer 320, and may be electrically connected to the upper pads 351 through the through-electrodes 330. The lower pads 341 may have flat lower surfaces, and may be coplanar with a lower surface of the lower insulating layer 345. The first lower pads 341a of the first semiconductor chip 300a located in the lowermost portion of the semiconductor chip stack 300 may be directly joined/bonded to the upper connection pads 151 of the base structure 100. Each of the second semiconductor chip 300b and the third semiconductor chips 300c of the semiconductor chip stack 300 may be directly joined/bonded to the upper pads 351 of a different semiconductor chip located therebelow through the respective lower pads 341. The lower pads 341 may be firmly joined/bonded by mutual diffusion of a metal (e.g., copper) through a high-temperature annealing process after being provisionally joined/attached to be in contact with the upper connection pads 151 or the upper pads 351. The lower pads 341 may include, but are not limited to, copper (Cu). For example, the lower pads 341 may include at least one of aluminum (Al), nickel (Ni), tungsten (W), platinum (Pt), or gold (Au). No separate solder may be disposed between the lower pads 341 and the upper connection pads 151, directly joined, or between the lower pads 341 and the upper pads 351. For example, no other material or layer may be interposed between the lower pads 341 and the upper connection pads 151 attached to each other, and between the lower pads 341 and the upper pads 351 attached to each other.

The lower insulating layer 345 may surround/contact side surfaces of the lower pads 341 below the semiconductor device layer 320. The lower insulating layer 345 may have a flat lower surface, and may be coplanar with lower surfaces of the lower pads 341. The first lower insulating layer 345a of the first semiconductor chip 300a may be directly joined/bonded to the upper bonding insulating layer 155. Each of the lower insulating layer 345 of the second semiconductor chip 300b and the lower insulating layers 345 of the third semiconductor chip 300c may be directly joined/bonded to the upper insulating layer 355 of a different semiconductor chip located therebelow. The lower insulating layers 345 may be in contact with the upper bonding insulating layer 155 or the upper insulating layers 355, and may be firmly joined/attached by bonding between dielectrics included therein. The lower insulating layers 345 may include an insulating material. The lower insulating layers 345 may include, for example, silicon oxide, silicon nitride, or a combination thereof, and may include a plurality of insulating layers.

The upper pads 351 may be disposed on the upper surface of the semiconductor substrate 310, and may be electrically connected to the lower pads 341 through the through-electrodes 330. The upper pads 351 may have flat upper surfaces, and may be coplanar with an upper surface of the upper insulating layer 355. The upper pads 351 of the first semiconductor chip 300a and the upper pads 351 of the third semiconductor chips 300c may be directly joined/bonded to the lower pads 341 of corresponding semiconductor chips located thereon. The upper pads 351 may have the same or similar characteristics as the lower pads 341 except that the upper pads 351 are located on an upper surface of each semiconductor chip. Second upper pads 351b of the second semiconductor chip 300b located in the uppermost portion of the semiconductor chip stack 300 may be covered by the joint film 410, and may be electrically isolated from the dummy chip 420.

The upper insulating layer 355 may surround/contact side surfaces of the upper pads 351 on the semiconductor substrate 310. The upper insulating layer 355 may have a flat upper surface, and may be coplanar with upper surfaces of the upper pads 351. Each of the upper insulating layer 355 of the first semiconductor chip 300a and the upper insulating layers 355 of the third semiconductor chips 300c may be directly joined/bonded to the lower insulating layer 345 of a different semiconductor chip located thereon. The upper insulating layer 355 may have the same characteristics as or similar characteristics to the lower insulating layer 345 except that each upper insulating layer 355 is located on a corresponding semiconductor substrate 310. A second upper insulating layer 355b of the second semiconductor chip 300b located in the uppermost portion of the semiconductor chip stack 300 may be covered by the joint film 410.

The joint film 410 may cover an upper surface of the uppermost semiconductor chip 300b, and may fix the dummy chip 420 on the semiconductor chip stack 300. The joint film 410 may be located between the semiconductor chip stack 300 and the dummy chip 420, and may prevent voids or stress that may occur when the semiconductor chip stack 300 and the dummy chip 420 are directly connected to each other. In addition, the process difficulty and process cost may be reduced compared to a case when the dummy chip 420 is directly disposed on the semiconductor chip stack 300. The joint film 410 may cover/contact at least a portion of the upper surface and at least a portion of the side surface of the uppermost semiconductor chip 300b. The joint film 410 may cover/contact a side surface of the dummy chip 420. An area of the joint film 410 covering/contacting a side surface of the dummy chip 420 may be smaller than an area of the joint film 410 covering/contacting a side surface of the uppermost semiconductor chip 300b. In an embodiment, the joint film 410 may not cover a side surface of the dummy chip 420. A level difference between a lower end of the joint film 410 and the upper surface of the uppermost semiconductor chip 300b may be larger than a level difference between an upper end of the joint film 410 and the upper surface of the uppermost semiconductor chip 300b. The joint film 410 may protrude further in the horizontal direction (for example, in the X-direction or the Y-direction) than each of the plurality of semiconductor chips 300a, 300b, and 300c and the dummy chip 420. In an embodiment, the joint film 410 may be, but is not limited to, a non-conductive film (NCF). The joint film 410 may include any kind of polymer film that may be subjected to a thermocompression process.

The dummy chip 420 may be disposed on the semiconductor chip stack 300, and the dummy chip 420 may be fixed on the uppermost semiconductor chip 300b by the joint film 410. The dummy chip 420 may be a dummy configuration/component disposed on the semiconductor chip stack 300 when a height of the semiconductor chip stack 300 is smaller than a height of a desired semiconductor package. Unlike the plurality of semiconductor chips 300a, 300b, and 300c and the base structure 100, in which the lower pads 341 and the lower insulating layers 345 are directly joined/attached to and fixed to the upper pads 351 and the upper insulating layers 355 therebelow, and/or the upper connection pads 151 and the upper bonding insulating layer 155, the dummy chip 420 may be fixed by the joint film 410 without contacting the uppermost semiconductor chip 300b. The dummy chip 420 may be spaced apart from the semiconductor chip stack 300 by the joint film 410. The dummy chip 420 may be electrically isolated from the plurality of semiconductor chips 300a, 300b, and 300c. The dummy chip 420 may have a thickness greater than a thickness of each of the plurality of semiconductor chips 300a, 300b, and 300c. A plan view area of the dummy chip 420 may be larger than a plan view area of each of the plurality of semiconductor chips 300a, 300b, and 300c. In the present specification, the plan view area may be an area in a plan view. Since the plan view area of the dummy chip 420 may be larger than the plan view area of each of the plurality of semiconductor chips 300a, 300b, and 300c, the joint film 410 may be prevented from protruding upward along the side surface of the dummy chip 420 during a bonding process of the dummy chip 420. Therefore, an upper end of the joint film 410 may be controlled not to extend to the upper surface of the dummy chip 420, and reliability of the semiconductor package may be improved. A horizontal width of the dummy chip 420 may be larger than a horizontal width of each of the plurality of semiconductor chips 300a, 300b, and 300c, and the dummy chip 420 may protrude further in the horizontal direction than each of the plurality of semiconductor chips 300a, 300b, and 300c. For example, the dummy chip 420 may protrude in horizontal directions from side surfaces of the plurality of semiconductor chips 300a, 300b, and 300c in all sides of the dummy chip 420. An upper surface of the dummy chip 420 may be exposed without being covered by the encapsulant 500. The upper surface of the dummy chip 420 may be coplanar with an upper surface of the encapsulant 500.

The encapsulant 500 may encapsulate the semiconductor chip stack 300 and the dummy chip 420 on the base structure 100. The encapsulant 500 may surround/contact side surfaces of the plurality of semiconductor chips 300a, 300b, and 300c and side surfaces of the dummy chip 420. The encapsulant 500 may be formed to expose the upper surface of the dummy chip 420. An upper surface of the encapsulant 500 may be coplanar with the upper surface of the dummy chip 420. The encapsulant 500 may have a high bonding force with the base structure 100 by the joint patterns 200, and may be stably joined/bonded with the base structure 100. The encapsulant 500 may include, for example, a thermosetting resin such as an epoxy resin, a thermoplastic resin such as a polyimide, or a prepreg, ABF, FR-4, BT, an epoxy molding compound (EMC), or the like.

To dispose the semiconductor chip stack 300 directly on the base structure 100 without a separate solder or the like, a process of forming the upper bonding insulating layer 155 on the upper surface of the base structure 100, and a process of planarizing the upper surface of the upper bonding insulating layer 155 may be performed. As surface roughness of the upper bonding insulating layer 155 is reduced by the planarization process, bonding force between the base structure 100 and the encapsulant 500 may be reduced. In addition, to form the semiconductor package in a desired/target size, the dummy chip 420 may be disposed on the semiconductor chip stack 300. In this case, to prevent voids or stress that may occur between and around the semiconductor chip stack 300 and the dummy chip 420, the joint film 410 may be disposed between the semiconductor chip stack 300 and the dummy chip 420. In a process of bonding the dummy chip 420 using the joint film 410, the joint film 410 may be partially detached and/or contaminate the upper surface of the base structure 100. Such contamination may weaken bonding force between the base structure 100 and the encapsulant 500. As bonding force between the base structure 100 and the encapsulant 500 weakens, delamination may occur therebetween, and in this case, the delamination may propagate into the semiconductor chip stack 300, thereby lowering reliability of the semiconductor package.

The present inventive concept may include the joint patterns 200 supplementing/reinforcing bonding force between the base structure 100 and the encapsulant 500, thereby preventing a delamination phenomenon that may occur between the base structure 100 and the encapsulant 500, and providing a semiconductor package having improved reliability. The joint patterns 200 may maintain a stable joined/attached state between the encapsulant 500 and the base structure 100 by including a material (e.g., a polymer) having strong bonding force with the encapsulant 500 and/or by increasing/reinforcing surface roughness of the upper surface of the base structure 100.

In the following description, descriptions overlapping the description made with reference to FIGS. 1 to 3 may be omitted for convenience of description.

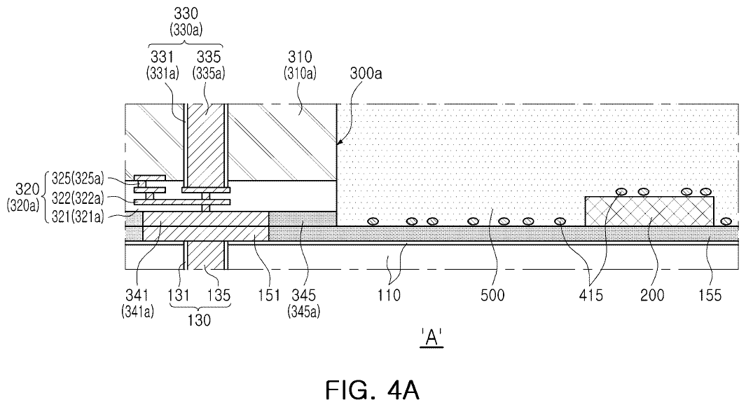

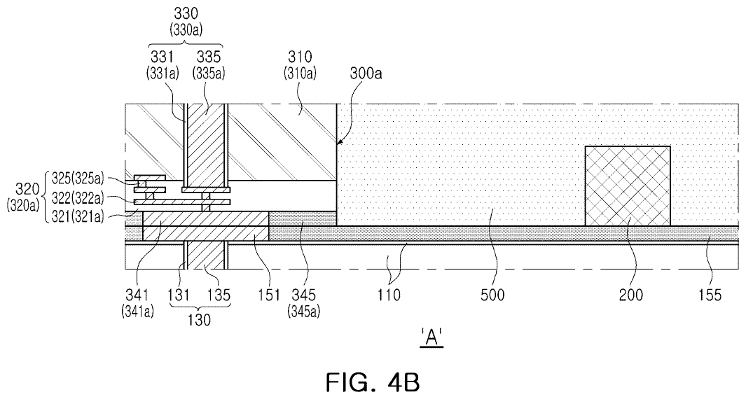

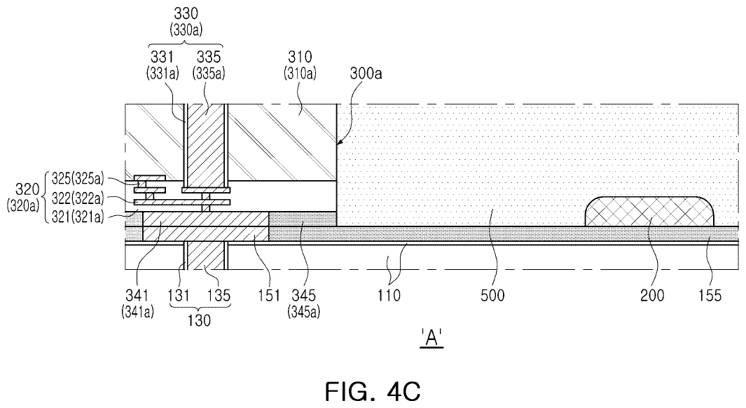

FIGS. 4A to 4C are schematic partial enlarged views illustrating a semiconductor package according to example embodiments. FIGS. 4A to 4C illustrate an area corresponding to portion ‘A’ of FIG. 1 in an enlarged manner.

Referring to FIG. 4A, a semiconductor package may further include joint debris 415. The joint debris 415 may be a configuration/particle formed by detachment from a joint film 410 during a process of forming the joint film 410 and a process of arranging a dummy chip 420. The joint debris 415 may include a material, the same as a material of the joint film 410. The joint debris 415 may be formed on an upper surface of a base structure 100, and may reduce bonding force between the base structure 100 and an encapsulant 500. The present inventive concept may include joint patterns 200 supplementing/reinforcing bonding force between the base structure 100 and the encapsulant 500, and, even though the joint debris 415 exists on the base structure 100, a phenomenon of the base structure 100 and the encapsulant 500 being peeled off from each other may be prevented.

Referring to FIG. 4B, unlike the embodiment of FIG. 3, each of joint patterns 200 may have a height greater than a width. Upper surfaces of the joint patterns 200 may be formed on a level, higher than a lower surface of a first semiconductor substrate 310 of a first semiconductor chip 300a. An aspect ratio of the joint patterns 200 is not limited to the embodiment of FIG. 3 or 4B, and may be variously modified. In a case in which the joint patterns 200 are formed by a deposition process and an etching process using a photoresist, upper surface corners of the joint patterns 200 may be formed in an angular shape, e.g., having a square angle in a cross-sectional view as illustrated in FIGS. 3 and 4B.

Referring to FIG. 4C, unlike the embodiment of FIG. 3, joint patterns 200 may have rounded upper surface corners. For example, the joint patterns 200 may have rounded upper corners in a cross-sectional view. Upper surface shapes of the joint patterns 200 may be variously modified depending on a process of forming the joint patterns 200. For example, side cross-sections of the joint patterns 200 may have semi-elliptical shapes, and/or the joint patterns 200 may have convex upper surfaces. In a case in which the joint patterns 200 are formed by a process of, e.g., printing a material forming the joint patterns 200 or dropping the material in droplets and curing the same, the joint patterns 200 in the shape of FIG. 4C may be formed. Depending on a process of forming the joint patterns 200, various types of joint patterns 200 may be formed, as well as the embodiments of FIGS. 3, 4B, and 4C. The embodiments of FIGS. 3, 4B, and 4C may also be applied to embodiments below.

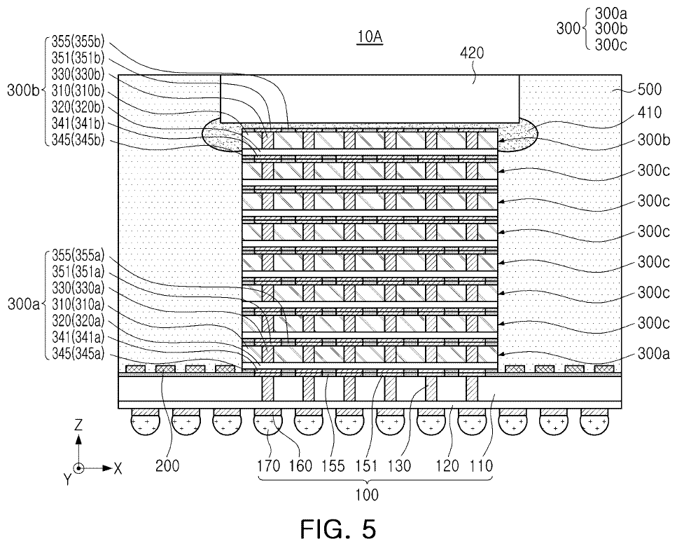

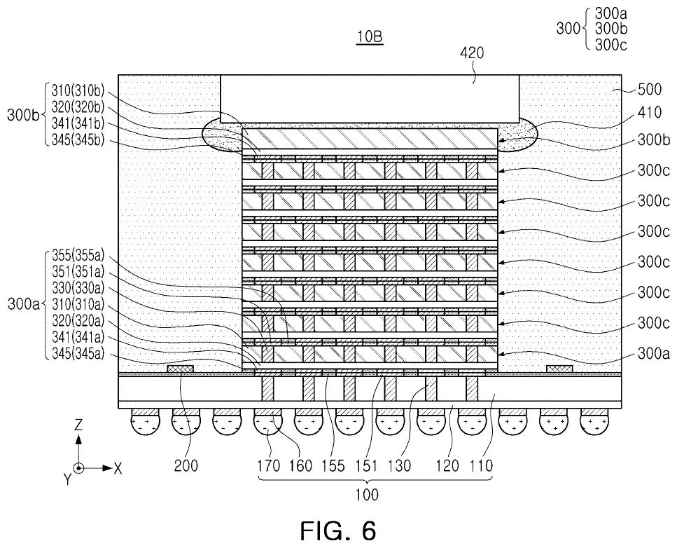

FIGS. 5 and 6 are schematic cross-sectional views illustrating a semiconductor package according to example embodiments. FIGS. 5 and 6 illustrate regions corresponding to FIG. 1.

Referring to FIG. 5, a portion of joint patterns 200 of a semiconductor package 10A may overlap a joint film 410 in the vertical direction. A portion of the joint patterns 200 may overlap a dummy chip 420 in the vertical direction. A portion of the joint patterns 200 may not overlap the joint film 410 and the dummy chip 420 in the vertical direction.

Referring to FIG. 6, an uppermost semiconductor chip 300b of a semiconductor package 10B, e.g., a second semiconductor chip 300b, may not include a second through-via 330b, second upper pads 351b, and a second upper insulating layer 355b, unlike the semiconductor package 10 of FIGS. 1 to 3. Since the dummy chip 420 may be configured to be electrically isolated from a plurality of semiconductor chips 300a, 300b, and 300c, the uppermost semiconductor chip 300b may not include configurations corresponding thereto.

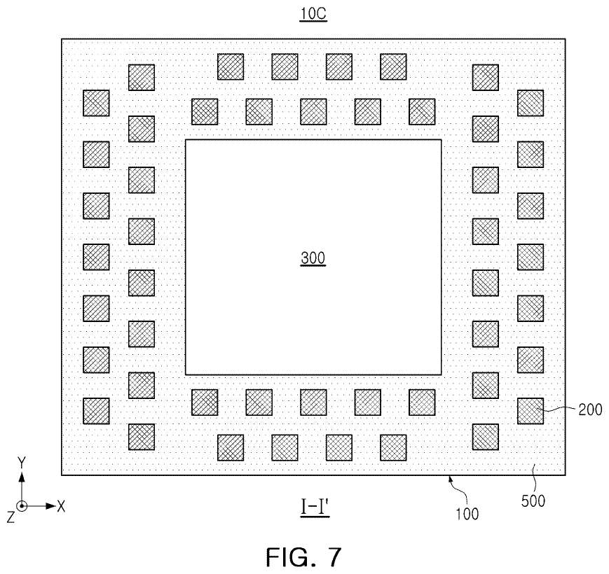

FIGS. 7 to 12 are schematic plan views illustrating a semiconductor package according to example embodiments. FIGS. 7 to 12 illustrate regions corresponding to FIG. 2.

Referring to FIG. 7, unlike the semiconductor package 10 of FIGS. 1 to 3, joint patterns 200 of a semiconductor package 10C may be disposed in multiple rows to surround a semiconductor chip stack 300. In an embodiment, inner and outer rows of the joint patterns 200 may be disposed in a zigzag arrangement. For example, the joint patterns 200 in an inner row and the joint patterns 200 in an outer row may not overlap each other in a horizontal direction perpendicular to an arrangement direction of the inner row joint patterns 200 and the outer row joint patterns 200. In an embodiment, unlike those illustrated, the inner and outer rows of the joint patterns 200 may be disposed in parallel. For example, the joint patterns 200 in an inner row and the joint patterns 200 in an outer row may overlap each other in a horizontal direction perpendicular to an arrangement direction of the inner row joint patterns 200 and the outer row joint patterns 200 in certain embodiments.

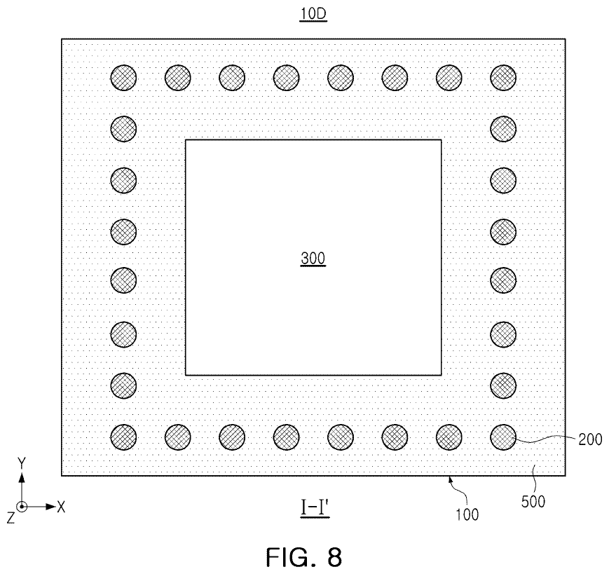

Referring to FIG. 8, unlike the semiconductor package 10 of FIGS. 1 to 3, joint patterns 200 of a semiconductor package 10D may have circular plan view shapes. The plan view shape of each of the joint patterns 200 is not limited to a tetragon or a circle, and may be variously modified to a polygon, an ellipse, or the like.

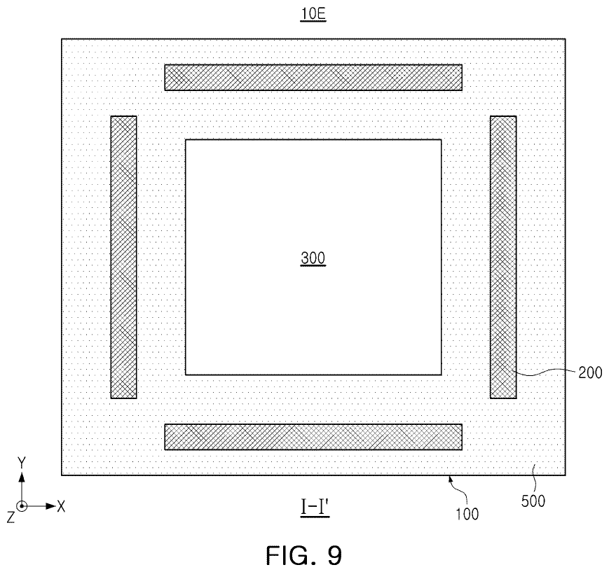

Referring to FIG. 9, unlike the semiconductor package 10 of FIGS. 1 to 3, each of joint patterns 200 of a semiconductor package 10E may be in the form of a bar extending lengthwise along an adjacent side surface of a semiconductor chip stack 300. A length of each of the joint patterns 200 may be longer than a length of the adjacent side surface of the semiconductor chip stack 300.

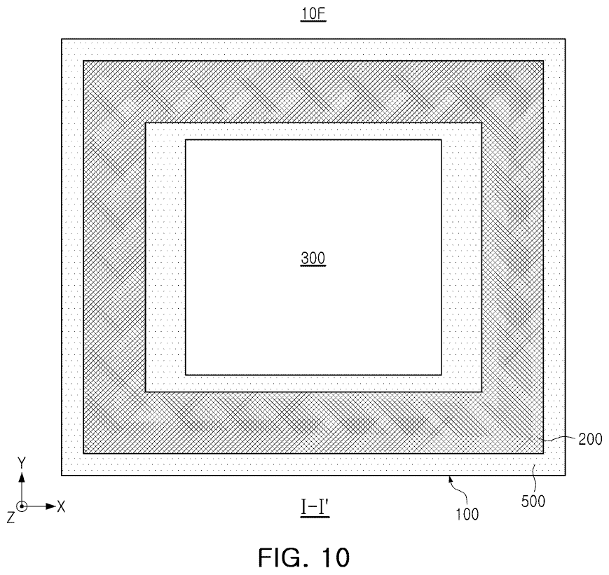

Referring to FIG. 10, unlike the semiconductor package 10 of FIGS. 1 to 3, a joint pattern 200 of a semiconductor package 10F may be in a shape of a ring surrounding a semiconductor chip stack 300. For example, the semiconductor package 10F may include a single joint pattern. An area in which an upper surface of a base structure 100 is in contact with the joint pattern 200 may be larger than an area in which the upper surface of the base structure 100 is in contact with an encapsulant 500.

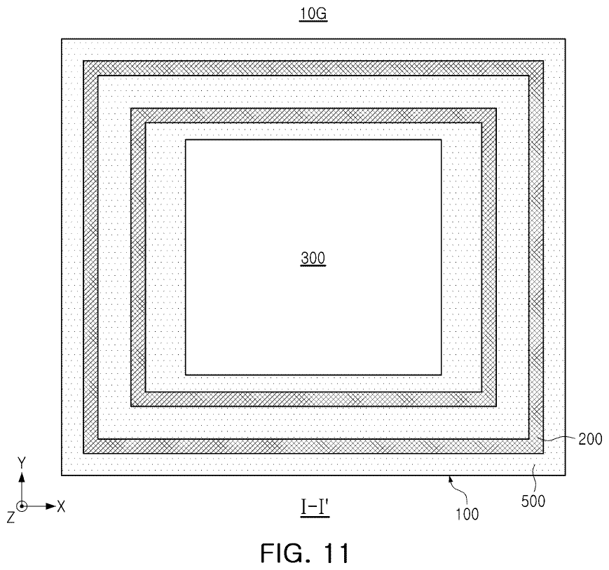

Referring to FIG. 11, unlike the semiconductor package 10F of FIG. 10, joint patterns 200 of a semiconductor package 10G may be formed in multiple numbers of ring shaped patterns, such that each of the joint patterns 200 have a ring shape surrounding a semiconductor chip stack 300. In an embodiment, the joint patterns 200 may be disposed in a greater number than those illustrated (e.g., three or more), and may surround the semiconductor chip stack 300.

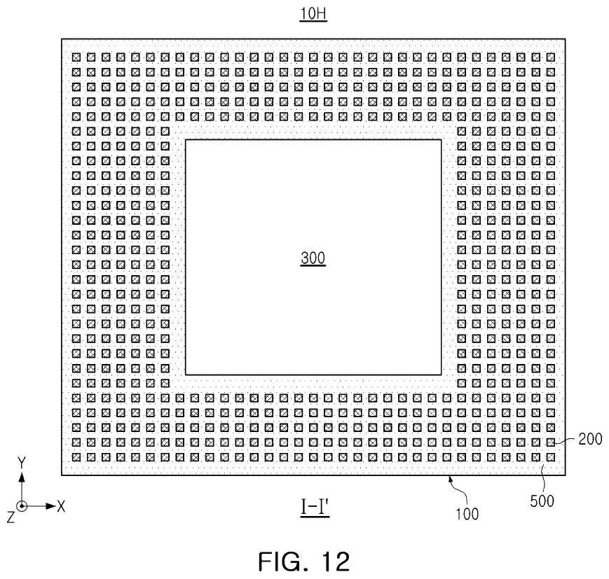

Referring to FIG. 12, unlike the semiconductor package 10 of FIGS. 1 to 3, joint patterns 200 of a semiconductor package 10H may be implemented as fine patterns in order to increase surface roughness of an upper surface of a base structure 100. Referring to FIGS. 1 to 3 together, an upper surface area of each of the joint patterns 200 may be smaller than an upper surface area of each of upper connection pads 151. In an embodiment, each of the joint patterns 200 may have a smaller plan view area than those illustrated in FIG. 12, and may be disposed in greater numbers.

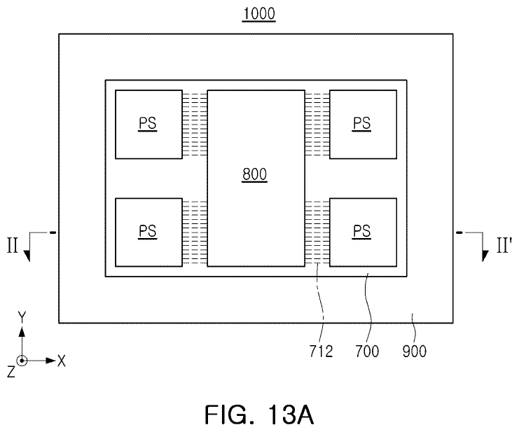

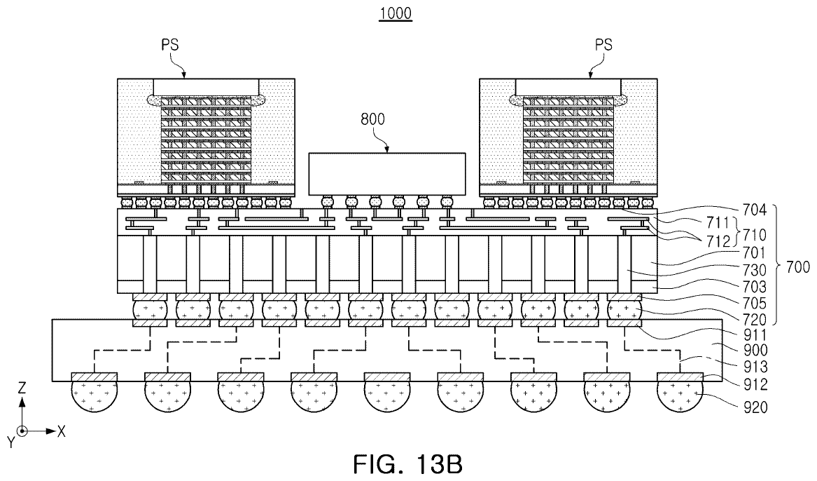

FIG. 13A is a schematic plan view illustrating a semiconductor package according to example embodiments.

FIG. 13B is a schematic cross-sectional view illustrating a semiconductor package according to example embodiments. FIG. 13B schematically illustrates a side cross-section of the semiconductor package of FIG. 13A, taken along line II-II'.

Referring to FIGS. 13A and 13B, a semiconductor package 1000 may include a package substrate 900, an interposer substrate 700, at least one chip structure PS, and a processor chip 800. Each of the at least one chip structure PS may have characteristics the same as or similar to one of the semiconductor packages 10, 10A, 10B, 10C, 10D, 10E, 10F, 10G, and 10H described with reference to FIGS. 1 to 12.

The package substrate 900 may be a support substrate on which the interposer substrate 700, the processor chip 800, and the chip structure PS are mounted, and may be a semiconductor package substrate including a printed circuit board (PCB), a ceramic substrate, a glass substrate, a tape wiring substrate, or the like. A body of the package substrate 900 may include different materials depending on a type of a substrate. For example, when the package substrate 900 is a printed circuit board, the semiconductor package 1000 may have a configuration in which an interconnection layer is additionally stacked on one surface or both surfaces of a body copper-clad laminate or a copper-clad laminate.

The package substrate 900 may include a lower terminal 912, an upper terminal 911, and a redistribution circuit 913. The upper terminal 911, the lower terminal 912, and the redistribution circuit 913 may form an electrical path electrically connecting between a lower surface and an upper surface of the package substrate 900. The upper terminal 911, the lower terminal 912, and the redistribution circuit 913 may include a metal material, for example, at least one metal from among copper (Cu), aluminum (Al), nickel (Ni), silver (Ag), gold (Au), platinum (Pt), tin (Sn), lead (Pb), titanium (Ti), chromium (Cr), palladium (Pd), indium (In), zinc (Zn), or carbon (C), or an alloy including two or more metals. An external connection terminal 920 electrically connected to and/or in contact with the lower terminal 912 may be disposed on the lower surface of the package substrate 900. The external connection terminal 920 may include tin (Sn), indium (In), bismuth (Bi), antimony (Sb), copper (Cu), silver (Ag), zinc (Zn), lead (Pb), and/or an alloy thereof.

The interposer substrate 700 may include a substrate 701, a lower protective layer 703, a metal pad 705, an interconnection structure 710, a metal bump 720, and a through-via 730. The chip structure PS and the processor chip 800 may be electrically connected to each other via the interposer substrate 700. In an embodiment, unlike those illustrated, the interposer substrate 700 may include a silicon bridge electrically connecting the chip structure PS and the processor chip 800.

The substrate 701 may be, for example, any one of a silicon substrate, an organic substrate, a plastic substrate, or a glass substrate. When the substrate 701 is the silicon substrate, the interposer substrate 700 may be a silicon interposer. Unlike those illustrated in the drawings, when the substrate 701 is the organic substrate, the interposer substrate 700 may be a panel interposer or an organic interposer.

The lower protective layer 703 may be disposed on a lower surface of the substrate 701, and the metal pad 705 may be disposed below the lower protective layer 703. The metal pad 705 may be electrically connected to and/or contact the through-via 730. The chip structure PS and the processor chip 800 may be electrically connected to the package substrate 900 through metal bumps 720 disposed below the metal pad 705.

The interconnection structure 710 may be disposed on an upper surface of the substrate 701, and may include an interlayer insulating layer 711 and a single-layer or multilayer interconnection structure 712. When the interconnection structure 710 is formed of a multilayer interconnection structure, interconnection patterns of different layers may be electrically connected to each other through a contact via.

The through-via 730 may extend from the upper surface of the substrate 701 to the lower surface thereof, and may penetrate the substrate 701. In addition, the through-via 730 may extend into an interior of the interconnection structure 710 and/or the lower protective layer 703, and may be electrically connected to interconnection patterns of the interconnection structure 710. When the substrate 701 is silicon, the through-via 730 may be a TSV. Depending on an embodiment, the interposer substrate 700 may include only the interconnection structure therein, and may not include a through-via.

The interposer substrate 700 may be used for converting or transmitting an input electrical signal between the package substrate 900 and the chip structure PS or the processor chip 800. Therefore, the interposer substrate 700 may not include components such as an active component, a passive component, or the like. In addition, depending on an embodiment, the interconnection structure 710 may be disposed below the through-via 730. For example, a positional relationship between the interconnection structure 710 and the through-via 730 may be relative/variable.

The metal bump 720 may electrically connect the interposer substrate 700 and the package substrate 900. The chip structure PS may be electrically connected to the metal bump 720 through the interconnection structure 710 and the through-via 730. According to an embodiment, the metal pads 705 used for power or ground may be integrated with the metal bump 720, such that the number of the metal pads 705 may be greater than the number of the metal bumps 720.

The processor chip 800 may include, for example, a central processor (CPU), a graphics processor (GPU), a field programmable gate array (FPGA), a digital signal processor (DSP), an encryption processor, a microprocessor, a microcontroller, an analog-to-digital converter, an application-specific integrated circuit (ASIC), or the like.

According to an embodiment, the semiconductor package 1000 may further include an inner encapsulant covering the chip structure PS and the processor chip 800 on the interposer substrate 700. In addition, the semiconductor package 1000 may further include an outer encapsulant covering the interposer substrate 700 and the inner encapsulant on the package substrate 900. The outer encapsulant and the inner encapsulant may be formed together, and may not be distinguished in certain embodiments. According to an embodiment, the semiconductor package 1000 may further include a heat dissipation structure covering the chip structure PS and the processor chip 800.

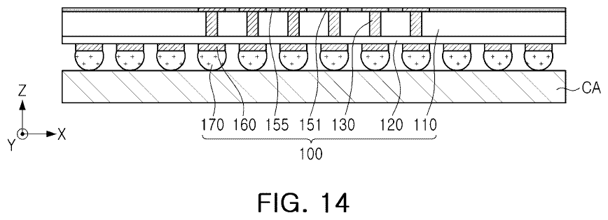

FIGS. 14, 15, 16A, 17A, and 18 are cross-sectional views illustrating in a process sequence a method for manufacturing a semiconductor package according to example embodiments. FIGS. 14, 15, 16A, 17A, and 18 illustrate a region corresponding to FIG. 1.

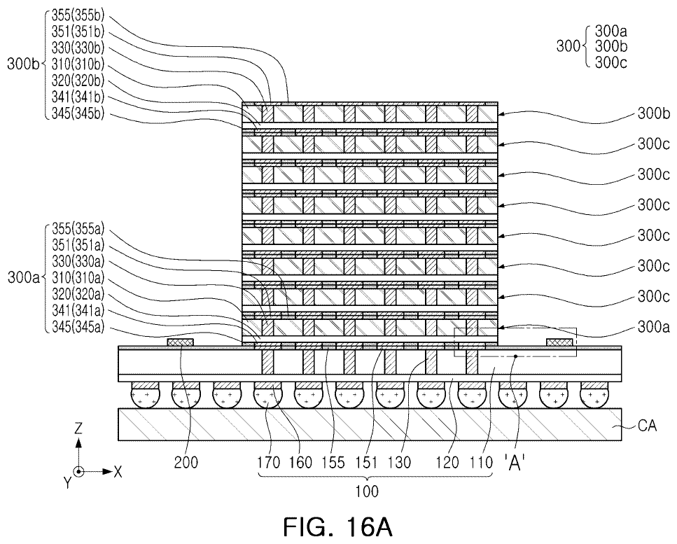

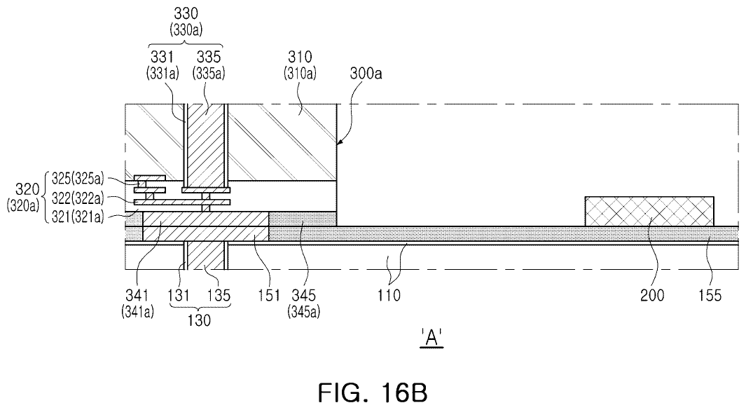

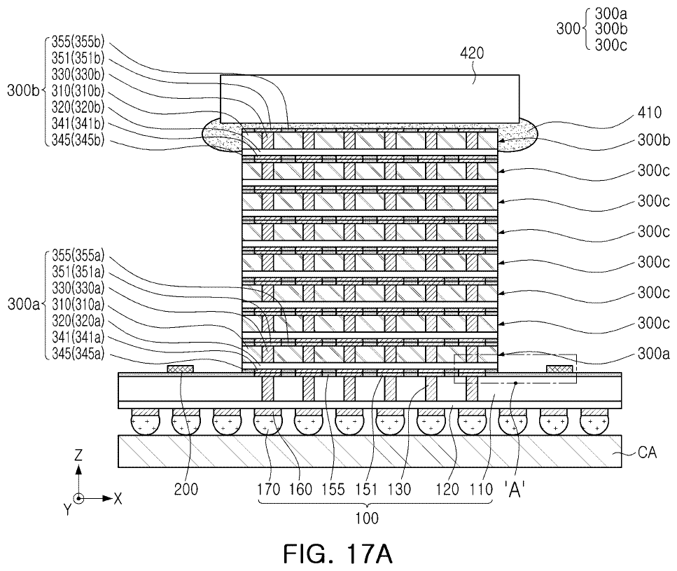

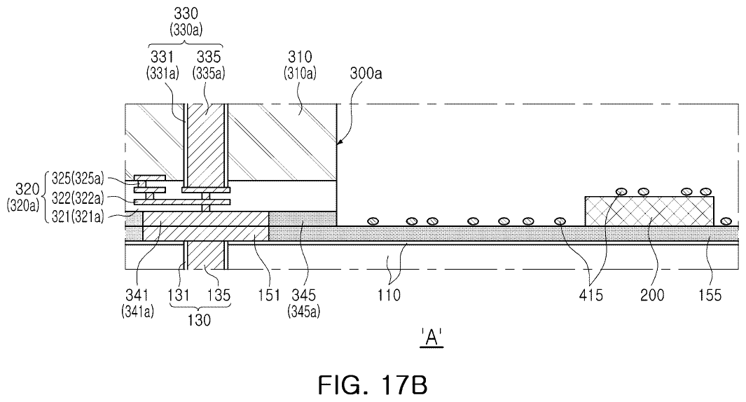

FIGS. 16B and 17B are partial enlarged views illustrating in a process sequence a method for manufacturing a semiconductor package according to example embodiments. FIGS. 16B and 17B illustrate a region corresponding to FIG. 4A.

Referring to FIG. 14, a base structure 100 may be formed on a carrier substrate CA.

Although FIG. 14 illustrates individual package units, processes described below may be performed on a wafer basis. For a bonding process to be performed thereafter, a process of planarizing an upper surface of the base structure 100 may be performed. The planarization process may be performed, for example, by a chemical mechanical polishing (CMP) process. By the planarization process, surface roughness of an upper bonding insulating layer 155 may be significantly reduced. An upper surface of the planarized upper bonding insulating layer 155 and upper surfaces of upper connection pads 151 may be coplanar and form a coplanar surface. In an embodiment, the upper surfaces of the upper connecting pads 151 may have a concave upper surface on a lower level than the upper surface of the upper bonding insulating layer 155.

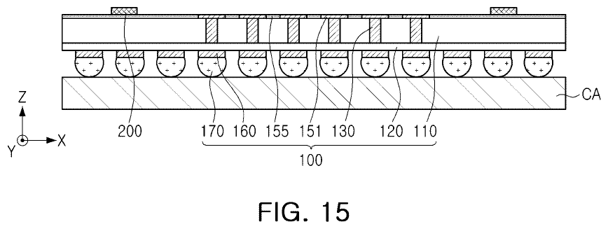

Referring to FIG. 15, joint patterns 200 may be formed on the upper bonding insulating layer 155 of the base structure 100.

The joint patterns 200 may be formed using a deposition process and an etching process using a photoresist, or by a process such as plating, deposition, printing, or the like, depending on a desired material or shape. The joint patterns 200 may not be formed in a space in which the semiconductor chip stack 300 of FIG. 1 is to be formed.

Referring to FIGS. 16A and 16B, a semiconductor chip stack 300 may be stacked on the base structure 100.

In an embodiment, a plurality of semiconductor chips 300a, 300b, and 300c may be stacked one by one as individual chip units. First, a first semiconductor chip 300a may be disposed such that first lower pads 341a and a first lower insulating layer 345a may be in contact with the upper connection pads 151 and the upper bonding insulating layer 155 of the base structure 100, respectively. By applying a certain/predetermined pressure to the first semiconductor chip 300a, the first lower pads 341a may be provisionally joined/attached to the upper connection pads 151, and the first lower insulating layer 345a may be provisionally joined/attached to the upper bonding insulating layer 155. A dielectric-to-dielectric bond may be formed between the first lower insulating layer 345a and the upper bonding insulating layer 155. Thereafter, through an annealing process, the first lower pads 341a and the upper connection pads 151 may be mutually expanded and firmly joined/bonded. By this process, the first semiconductor chip 300a may be mounted such that a lower surface of the first semiconductor chip 300a is in contact with an upper surface of the base structure 100 without a separate solder interposed therebetween. In the same manner, third semiconductor chips 300c and a second semiconductor chip 300b may be sequentially stacked on the first semiconductor chip 300a to form a semiconductor chip stack 300 on the base structure 100. In an embodiment, a plurality of previously coupled semiconductor chips (e.g., a semiconductor chip stack 300) may be mounted on the base structure 100.

Referring to FIGS. 17A and 17B, a joint film 410 and a dummy chip 420 may be formed on the semiconductor chip stack 300.

Since the dummy chip 420 may be configured not to be electrically connected to the semiconductor chip stack 300, unlike a process of stacking the plurality of semiconductor chips 300a, 300b, and 300c in FIGS. 16A and 16B, the dummy chip 420 may be stacked using the joint film 410. In a process of fixing the dummy chip 420 onto the semiconductor chip stack 300 using the joint film 410, the joint film 410 may protrude in the horizontal direction and may cover a side surface of the uppermost semiconductor chip 300b. As the dummy chip 420 is disposed on the semiconductor chip stack 300 using the joint film 410, voids or stresses that may occur between and around the semiconductor chip stack 300 and the dummy chip 420 may be prevented or reduced. As a plan view area of the dummy chip 420 is formed to be larger than a plan view area of each of the plurality of semiconductor chips 300a, 300b, and 300c, the joint film 410 may be formed to cover the side surface of the uppermost semiconductor chip 300b more than a side surface of the dummy chip 420, and the upper end of the joint film 410 may be controlled not to be formed on an excessively higher level than a lower surface of the dummy chip 420. Therefore, an upper end of the joint film 410 may not extend to an upper surface of the dummy chip 420. In this operation, a portion of the joint film 410 may be detached to form joint debris 415 on the base structure 100.

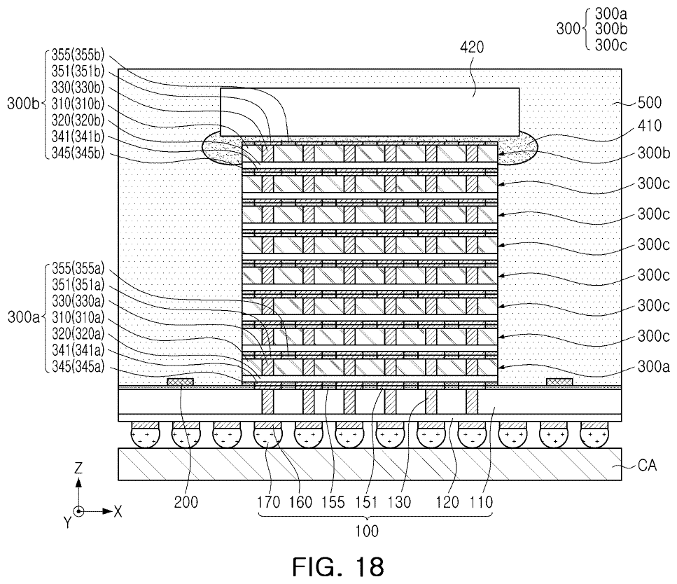

Referring to FIG. 18, an encapsulant 500 covering the joint patterns 200, the semiconductor chip stack 300, the joint film 410, and the dummy chip 420 may be formed.

A lower surface of the encapsulant 500 may be in contact with the upper bonding insulating layer 155 of the base structure 100 and the joint patterns 200. The upper bonding insulating layer 155 may have a flattened upper surface by a CMP process or the like, and in this case, bonding force may be weakened, e.g., compared with a bonding insulating layer having a rough upper surface, as a contact area with the lower surface of the encapsulant 500 decreases. In addition, bonding force between the encapsulant 500 and the base structure 100 may be further weakened by the joint debris 415 formed on the upper bonding insulating layer 155. Since the embodiments may include the joint patterns 200 supplementing/enhancing bonding force between the encapsulant 500 and the base structure 100, it may be possible to prevent/reduce the phenomenon in which the lower surface of the encapsulant 500 is peeled off from the upper surface of the base structure 100, and to provide a semiconductor package having improved reliability. The joint patterns 200 may increase bonding force between the encapsulant 500 and the base structure 100 by using a material (e.g., a polymer) having good bonding force (e.g., chemically) with the encapsulant 500, and/or by increasing surface roughness of the upper bonding insulating layer 155 to increase a contact area with the lower surface of the encapsulant 500.

Referring to FIG. 1 together with FIG. 18, the encapsulant 500 may be partially removed from an upper surface such that an upper surface of the dummy chip 420 is exposed, e.g., from the encapsulant 500, and the semiconductor package of the embodiment illustrated in FIG. 1 may be manufactured. Etching of the encapsulant 500 may be performed, for example, by a process such as grinding or the like.

According to embodiments, by arranging joint patterns having improved bonding force between a base structure and an encapsulant, a semiconductor package having improved reliability may be provided.

Even though different figures illustrate variations of exemplary embodiments and different embodiments disclose different features from each other, these figures and embodiments are not necessarily intended to be mutually exclusive from each other. Rather, features depicted in different figures and/or described above in different embodiments can be combined with other features from other figures/embodiments to result in additional variations of embodiments, when taking the figures and related descriptions of embodiments as a whole into consideration. For example, components and/or features of different embodiments described above can be combined with components and/or features of other embodiments interchangeably or additionally to form additional embodiments unless the context clearly indicates otherwise, and the present disclosure includes the additional embodiments.

Advantages and effects of the present inventive concept are not limited to the above-described contents, and will be more easily understood in the process of explaining/understanding specific embodiments.

While example embodiments have been illustrated and described above, it will be apparent to those skilled in the art that modifications and variations could be made without departing from the scope of the present invention as defined by the appended claims.

What is claimed is:

1. A semiconductor package comprising:
a base structure including a base substrate, upper connection pads on an upper surface of the base substrate, and an upper bonding insulating layer covering the upper surface of the base substrate and surrounding side surfaces of the upper connection pads;
a semiconductor chip stack stacked on the base structure in a vertical direction and electrically connected to the base structure, and including a plurality of semiconductor chips having lower pads located on a lower surface, upper pads on an upper surface, and through-electrodes electrically connecting the lower pads and the upper pads, wherein the plurality of semiconductor chips include a lowermost semiconductor chip, and the lower pads of the lowermost semiconductor chip are in contact with the upper connection pads;
a dummy chip on the semiconductor chip stack;
a joint film between the dummy chip and the semiconductor chip stack;
a plurality of joint patterns spaced apart from the plurality of semiconductor chips on the base structure; and
an encapsulant covering at least a portion of the semiconductor chip stack, the dummy chip, the joint film, and each of the plurality of joint patterns, on the base structure,
wherein the lower pads of the semiconductor chips stacked on the lowermost semiconductor chip among the plurality of semiconductor chips are in contact with the upper pads of the semiconductor chips respectively disposed therebelow.

2. The semiconductor package of claim 1, wherein a plan view area of the dummy chip is larger than a plan view area of each of the plurality of semiconductor chips.

3. The semiconductor package of claim 1, wherein the plurality of joint patterns are disposed on the upper bonding insulating layer and spaced apart from the base substrate.

4. The semiconductor package of claim 1, wherein the plurality of joint patterns include a polymer.

5. The semiconductor package of claim 1, wherein
the dummy chip is spaced apart from the semiconductor chip stack by the joint film, and
the dummy chip is electrically isolated from the plurality of semiconductor chips.

6. The semiconductor package of claim 1, wherein a level difference between an upper surface of an uppermost semiconductor chip among the plurality of semiconductor chips and a lower end of the joint film is greater than a level difference between the upper surface of the uppermost semiconductor chip and an upper end of the joint film.

7. The semiconductor package of claim 1, wherein an upper surface of each of the plurality of joint patterns is located on a higher level than an upper surface of each of the lower pads of the lowermost semiconductor chip.

8. The semiconductor package of claim 1, wherein the plurality of joint patterns include metal.

9. The semiconductor package of claim 1, wherein
the base structure comprises:
lower connection pads below a lower surface of the base substrate and electrically connected to the upper connection pads;
connection vias extending in the base substrate in the vertical direction and electrically connecting the upper connection pads and the lower connection pads; and
connection conductors below the lower connection pads.

10. The semiconductor package of claim 1, wherein a thickness of the dummy chip is greater than a thickness of each of the plurality of semiconductor chips.

11. The semiconductor package of claim 1, wherein an upper surface of the encapsulant is coplanar with an upper surface of the dummy chip.

12. The semiconductor package of claim 1, wherein each of the plurality of semiconductor chips is a memory chip.

13. The semiconductor package of claim 1, further comprising joint debris buried by the encapsulant on the upper surface of the base structure,
wherein the joint debris include a material, the same as a material of the joint film.

14. A semiconductor package comprising:
a base structure including a base substrate and upper connection pads on an upper surface of the base substrate;
a semiconductor chip stack including a plurality of semiconductor chips stacked on the base structure in a vertical direction;
a joint pattern spaced apart from the semiconductor chip stack on the base structure;
a joint film covering an upper portion of the semiconductor chip stack; and
a dummy chip on the joint film,
wherein the plurality of semiconductor chips include:
a first semiconductor chip located in a lowermost portion of the semiconductor chip stack, and including first lower pads on a lower surface, first upper pads on an upper surface, and first through-electrodes electrically connecting the first lower pads and the first upper pads; and
a second semiconductor chip located in an uppermost portion of the semiconductor chip stack and including second lower pads on a lower surface,
the first lower pads are in contact with the upper connection pads,
the joint film protrudes further in a horizontal direction than each of the dummy chip and the plurality of semiconductor chips, and
the joint film covers at least a portion of a side surface of the second semiconductor chip.

15. The semiconductor package of claim 14, wherein the joint pattern overlaps the joint film in the vertical direction.

16. The semiconductor package of claim 14, wherein an area of the joint film covering a side surface of the dummy chip is smaller than an area of the joint film covering the side surface of the second semiconductor chip, or the joint film does not cover the side surface of the dummy chip.

17. The semiconductor package of claim 14, wherein
the plurality of semiconductor chips further include third semiconductor chips stacked between the first semiconductor chip and the second semiconductor chip, and
each of the third semiconductor chips includes third lower pads on a lower surface, third upper pads on an upper surface, and third through-electrodes electrically connecting the third lower pads and the third upper pads,
the third lower pads of a third semiconductor chip disposed most adjacent to the first semiconductor chip, among the third semiconductor chips, are in contact with the first upper pads of the first semiconductor chip, and
the third upper pads of a third semiconductor chip disposed most adjacent to the second semiconductor chip, among the third semiconductor chips, are in contact with the second lower pads of the second semiconductor chip.

18. The semiconductor package of claim 14, wherein the joint pattern extends along side surfaces of the first semiconductor chip.

19. A semiconductor package comprising:
a base structure including a base substrate, upper connection pads on an upper surface of the base substrate, and an upper bonding insulating layer covering the upper surface of the base substrate and surrounding side surfaces of the upper connection pads;
a semiconductor chip stack on the base structure and electrically connected to the upper connection pads, wherein the semiconductor chip stack includes a lowermost semiconductor chip located on a lowermost level;
joint patterns on the upper bonding insulating layer to be spaced apart from the semiconductor chip stack; and
an encapsulant covering the semiconductor chip stack and the joint patterns on the upper surface of the base substrate,
wherein the lowermost semiconductor chip includes lower pads on a lower surface, and a lower insulating layer surrounding side surfaces of the lower pads,
the lower pads are in contact with the upper connection pads, and
the lower insulating layer is in contact with the upper bonding insulating layer.

20. The semiconductor package of claim 19, wherein
upper surfaces of the upper connection pads are coplanar with an upper surface of the upper bonding insulating layer, and
lower surfaces of the lower pads are coplanar with a lower surface of the lower insulating layer.
